(19) United States
(12) Patent Application Publication
(10) Pub. No.: US 2026/0255627 A1
(43) Pub. Date: Aug. 27, 2026

(54) NITRIDE SEMICONDUCTOR DEVICE

(71) Applicant: Panasonic Holdings Corporation, Osaka (JP)

(72) Inventors: NAOKI TORII, Osaka (JP); MASAO KAWAGUCHI, Kyoto (JP); SATOSHI TAMURA, Osaka (JP)

(21) Appl. No.: 19/534,521

(22) Filed: Feb. 9, 2026

(30) Foreign Application Priority Data
Feb. 26, 2025 (JP) 2025-028865

(51) Int. Cl. H10D 30/47; H10D 62/17; H10D 62/824; H10D 62/85

(52) U.S. Cl. CPC H10D 30/475; H10D 30/4755; H10D 62/343; H10D 62/824; H10D 62/8503

(57) ABSTRACT

A device includes an n-type first nitride semiconductor layer, a p-type second nitride semiconductor layer, an electron transport layer and an electron supply layer covering an inner surface of an opening that penetrates the second nitride semiconductor layer and reaches the first nitride semiconductor layer, and above the second nitride semiconductor layer, a p-type third nitride semiconductor layer, an intermediate layer disposed between the electron supply layer and the third nitride semiconductor layer at a position overlapping the opening, a gate electrode disposed above the electron supply layer at a position overlapping the second nitride semiconductor layer without overlapping the opening, a source electrode disposed above the second nitride semiconductor layer and apart from the gate electrode, and a shielding electrode disposed above the third nitride semiconductor layer at a position overlapping the opening. A side surface of the intermediate layer is covered with the third nitride semiconductor layer.

### BACKGROUND

### 1. Technical Field

The present disclosure relates to a nitride semiconductor device.

### 2. Description of the Related Art

Patent Literature (PTL) 1 discloses a nitride semiconductor device including a two-dimensional electron gas (2DEG) as a channel. In the nitride semiconductor device disclosed in PTL 1, a p-type semiconductor layer is provided immediately below a gate electrode. The potential of a conduction band edge of the channel portion is raised by the p-type semiconductor layer, a threshold value can be increased, and normally-off operation of the transistor can be realized.

PTL 1: Japanese Patent No. 6511645

### SUMMARY

A nitride semiconductor device according to one aspect of the present disclosure includes: a substrate; a first nitride semiconductor layer of n-type disposed above the substrate; a second nitride semiconductor layer of p-type disposed above the first nitride semiconductor layer; an electron transport layer and an electron supply layer each disposed in order from the substrate side, the electron transport layer and the electron supply layer covering an inner surface of a first opening that penetrates the second nitride semiconductor layer and reaches the first nitride semiconductor layer, and covering above the second nitride semiconductor layer; a third nitride semiconductor layer of p-type disposed above the electron supply layer; an intermediate layer disposed between the electron supply layer and the third nitride semiconductor layer at a position overlapping the first opening in plan view of the substrate; a gate electrode disposed above the electron supply layer at a position overlapping the second nitride semiconductor layer without overlapping the first opening in plan view of the substrate; a source electrode disposed above the second nitride semiconductor layer and apart from the gate electrode; a shielding electrode disposed above the third nitride semiconductor layer at a position overlapping the first opening in plan view of the substrate, and electrically connected to the source electrode; and a drain electrode disposed below the substrate, in which the intermediate layer includes a side surface covered with the third nitride semiconductor layer.

### BRIEF DESCRIPTION OF THE DRAWINGS

FIG. 1 is a cross-sectional view of a nitride semiconductor device according to a first exemplary embodiment;

FIG. 2 is a cross-sectional view of a nitride semiconductor device according to a second exemplary embodiment;

FIG. 3 is a cross-sectional view of a nitride semiconductor device according to a third exemplary embodiment;

FIG. 4 is a cross-sectional view of a nitride semiconductor device according to a fourth exemplary embodiment;

FIG. 5 is a cross-sectional view of a nitride semiconductor device according to a fifth exemplary embodiment; and

FIG. 6 is a cross-sectional view of a nitride semiconductor device according to a sixth exemplary embodiment.

### DETAILED DESCRIPTIONS

The above-described conventional nitride semiconductor device has a problem that the concentration of the 2DEG decreases due to the influence of a depletion layer extending from the p-type semiconductor layer, and the on-resistance increases.

Therefore, the present disclosure provides a nitride semiconductor device capable of reducing on-resistance.

### Summary of present disclosure

A nitride semiconductor device according to a first aspect of the present disclosure includes: a substrate; a first nitride semiconductor layer of n-type disposed above the substrate; a second nitride semiconductor layer of p-type disposed above the first nitride semiconductor layer; an electron transport layer and an electron supply layer each disposed in order from the substrate side, the electron transport layer and the electron supply layer covering an inner surface of a first opening that penetrates the second nitride semiconductor layer and reaches the first nitride semiconductor layer, and covering above the second nitride semiconductor layer; a third nitride semiconductor layer of p-type disposed above the electron supply layer; an intermediate layer disposed between the electron supply layer and the third nitride semiconductor layer at a position overlapping the first opening in plan view of the substrate; a gate electrode disposed above the electron supply layer at a position overlapping the second nitride semiconductor layer without overlapping the first opening in plan view of the substrate; a source electrode disposed above the second nitride semiconductor layer and apart from the gate electrode; a shielding electrode disposed above the third nitride semiconductor layer at a position overlapping the first opening in plan view of the substrate, and electrically connected to the source electrode; and a drain electrode disposed below the substrate, in which the intermediate layer includes a side surface covered with the third nitride semiconductor layer.

As a result, a 2DEG is generated in the vicinity of an interface between the electron transport layer and the electron supply layer, and can be used as a channel. In a region overlapping the p-type third nitride semiconductor layer in plan view, the potential of a conduction band edge of the channel can be increased. Therefore, the nitride semiconductor device can be operated as a normally-off transistor. At this time, in a region overlapping the intermediate layer in plan view, the influence of the third nitride semiconductor layer on the channel can be suppressed. A decrease in the concentration of the 2DEG can be suppressed, and the on-resistance can be reduced. Furthermore, since the side surface of the intermediate layer is covered with the third nitride semiconductor layer, a leak current via the side surface of the intermediate layer can be reduced.

A nitride semiconductor device according to a second aspect of the present disclosure is the nitride semiconductor device according to the first aspect, in which the third nitride semiconductor layer includes: a shielding portion that overlaps the first opening in plan view of the substrate and is electrically connected to the shielding electrode; and a gate portion that overlaps an upper surface of the second nitride semiconductor layer in plan view of the substrate and is electrically connected to the gate electrode.

As a result, by providing the shielding electrode electrically connected to the source electrode and the shielding portion, the shielding electrode and the shielding portion can terminate the line of electric force extending from the drain electrode. The parasitic capacitance between the gate and the drain can be reduced, and the switching speed can be increased. Furthermore, since on and off of the transistor are controlled by the gate portion, the transistor is hardly affected by an inclined portion of the channel. Therefore, controllability of on and off of the transistor can be enhanced.

A nitride semiconductor device according to a third aspect of the present disclosure is the nitride semiconductor device according to the second aspect, in which the side surface of the intermediate layer is covered with the shielding portion.

As a result, a leak current via the side surface of the intermediate layer can be reduced.

A nitride semiconductor device according to a fourth aspect of the present disclosure is the nitride semiconductor device according to the third aspect, in which an end of the shielding portion on the source electrode side overlaps an upper surface of the second nitride semiconductor layer in plan view of the substrate.

As a result, since an area in which the p-type shielding portion and the p-type second nitride semiconductor layer overlap each other is increased, the shielding effect can be enhanced, and the parasitic capacitance between the gate and the drain can be further reduced.

A nitride semiconductor device according to a fifth aspect of the present disclosure is the nitride semiconductor device according to the third aspect, in which an end of the shielding portion on the source electrode side overlaps an inclined surface of the first opening in plan view of the substrate.

As a result, an area in which the p-type shielding portion is in contact with the electron supply layer without interposing the intermediate layer is reduced, so that a decrease in the concentration of the 2DEG can be suppressed, and the on-resistance can be reduced.

A nitride semiconductor device according to a sixth aspect of the present disclosure is the nitride semiconductor device according to the second aspect, in which the side surface of the intermediate layer is covered with the gate portion.

As a result, a leak current via the side surface of the intermediate layer can be reduced. Furthermore, since an area of the intermediate layer is increased, a decrease in the concentration of the 2DEG can be further suppressed, and the on-resistance can be further reduced.

A nitride semiconductor device according to a seventh aspect of the present disclosure is the nitride semiconductor device according to any one of the first aspect to the sixth aspect, in which the intermediate layer includes a GaN layer including GaN as a main component, and an AlGaN layer disposed above the GaN layer and including AlGaN as a main component.

As a result, an interface between the GaN layer and each of the p-type shielding layer and a p-type threshold value adjustment layer can be prevented from being exposed, so that the leak current can be reduced. Furthermore, a difference in an etching rate between the AlGaN layer and the GaN layer can be utilized, and the etching process can be easily performed.

A nitride semiconductor device according to an eighth aspect of the present disclosure is the nitride semiconductor device according to the seventh aspect, in which the AlGaN layer has an Al composition ratio of more than or equal to 10%.

As a result, the effect of reducing the leak current can be enhanced. Furthermore, since a difference in the etching rate with respect to the GaN layer can be increased, the etching process can be more easily performed.

A nitride semiconductor device according to a ninth aspect of the present disclosure is the nitride semiconductor device according to any one of the first aspect to the eighth aspect, in which the electron supply layer includes Al, and the electron supply layer has an Al composition ratio of more than or equal to 10%.

As a result, a polarization amount can be increased, and the concentration of the 2DEG can be increased.

A nitride semiconductor device according to a tenth aspect of the present disclosure is the nitride semiconductor device according to any one of the second aspect to the ninth aspect, in which the electron supply layer includes a recess at a position overlapping the upper surface of the second nitride semiconductor layer in plan view of the substrate, and the gate portion is disposed in contact with at least a part of a bottom surface of the recess.

As a result, a threshold value of the transistor can be adjusted by a depth of the recess. For example, normally-off of the transistor can be easily realized. Furthermore, since a portion other than the recess of the electron supply layer can be thickened, the concentration of the 2DEG can be increased in the thickened portion. Therefore, it is possible to achieve both the normally-off and the reduction in the on-resistance.

A nitride semiconductor device according to an eleventh aspect of the present disclosure is the nitride semiconductor device according to any one of the second aspect to the tenth aspect, in which the electron supply layer includes an upper surface that is a flat surface between the source electrode and the shielding portion and within a range overlapping the upper surface of the second nitride semiconductor layer in plan view of the substrate.

As a result, it is not necessary to form the recess, so that the stability of the process can be enhanced.

A nitride semiconductor device according to a twelfth aspect of the present disclosure is the nitride semiconductor device according to any one of the first aspect to the eleventh aspect, in which the source electrode is electrically connected to the second nitride semiconductor layer via a second opening that penetrates the electron supply layer and the electron transport layer and reaches the second nitride semiconductor layer.

As a result, a reverse bias can be applied to a pn junction between the p-type second nitride semiconductor layer and the n-type first nitride semiconductor layer via the source electrode and the drain electrode. Therefore, the withstand voltage of the vertical transistor can be increased.

A nitride semiconductor device according to a thirteenth aspect of the present disclosure is the nitride semiconductor device according to the twelfth aspect, and includes a fourth nitride semiconductor layer of p-type disposed in contact with the second nitride semiconductor layer in the second opening, in which the source electrode is in contact with the fourth nitride semiconductor layer.

Etching damage may occur in the second nitride semiconductor layer when the second opening is formed. Therefore, in a case where the second nitride semiconductor layer and the source electrode are brought into contact with each other, good contact cannot be obtained, and contact resistance may increase. On the other hand, according to the present aspect, since the source electrode and the second nitride semiconductor layer are electrically connected via the fourth nitride semiconductor layer, the contact resistance can be reduced.

A nitride semiconductor device according to a fourteenth aspect of the present disclosure is the nitride semiconductor device according to any one of the first aspect to the thirteenth aspect, in which the intermediate layer includes a nitride semiconductor as a main component.

As a result, the electron supply layer and the intermediate layer can be continuously formed by epitaxial growth. Since a defect level is less likely to be formed at the interface, the operation of the transistor can be stabilized.

A nitride semiconductor device according to a fifteenth aspect of the present disclosure is the nitride semiconductor device according to any one of the first aspect to the fourteenth aspect, in which the intermediate layer has an n-type conductivity.

As a result, the potential of the conduction band edge of the channel raised by the p-type third nitride semiconductor layer can be pushed down by the n-type intermediate layer. Therefore, a decrease in the concentration of the 2DEG can be suppressed, and the on-resistance can be reduced. Furthermore, the n-type intermediate layer can suppress diffusion of p-type impurities from the p-type third nitride semiconductor layer. It is possible to cancel the p-type conversion of the n-type intermediate layer due to the p-type impurities, and the expansion of a depletion region is suppressed. Therefore, a decrease in the concentration of the 2DEG can be suppressed, and the on-resistance can be reduced.

A nitride semiconductor device according to a sixteenth aspect of the present disclosure is the nitride semiconductor device according to the fifteenth aspect, in which the intermediate layer has a carrier concentration of more than or equal to 2 × 10¹⁷ cm⁻³.

As a result, the potential of the conduction band edge of the channel can be sufficiently pushed down. Therefore, a decrease in the concentration of the 2DEG can be suppressed, and the on-resistance can be reduced.

A nitride semiconductor device according to a seventeenth aspect of the present disclosure is the nitride semiconductor device according to any one of the first aspect to the fourteenth aspect, in which the intermediate layer has an i-type conductivity.

As a result, the i-type intermediate layer can suppress diffusion of p-type impurities from the p-type third nitride semiconductor layer. Since the expansion of a depletion region accompanying the expansion of a p-type region is suppressed, it is possible to suppress a decrease in the concentration of the 2DEG and to reduce the on-resistance.

A nitride semiconductor device according to an eighteenth aspect of the present disclosure is the nitride semiconductor device according to the seventeenth aspect, in which the intermediate layer includes p-type impurities.

As a result, the i-type intermediate layer can suppress diffusion of p-type impurities.

A nitride semiconductor device according to a nineteenth aspect of the present disclosure is the nitride semiconductor device according to any one of the first aspect to the eighteenth aspect, in which the intermediate layer has a film thickness of from 20 nm to 500 nm inclusive.

This can effectively suppress diffusion of the p-type impurities.

Hereinafter, exemplary embodiments will be specifically described with reference to the drawings.

Note that the exemplary embodiment described hereinafter provides comprehensive or specific examples. Numerical values, shapes, materials, constituent elements, arrangement positions and connection modes of the constituent elements, steps, order of the steps, and the like shown in the following exemplary embodiment are merely examples, and are not intended to limit the present disclosure. Moreover, among the constituent elements in the following exemplary embodiments, constituent elements not recited in the independent claims are described as arbitrary constituent elements.

Furthermore, each of the drawings is a schematic diagram, and is not necessarily strictly illustrated. Therefore, for example, scales and the like are not necessarily matched in the respective drawings. Furthermore, in each drawing, substantially identical components are denoted by identical reference signs, and the redundant description will be omitted or simplified.

Furthermore, in the present specification, the term indicating the relationship between elements such as parallel and orthogonal, the term indicating the shape of an element such as a rectangle, and the numerical range are not expressions representing only a strict meaning, but are expressions meaning to include a substantially equivalent range, for example, a difference of about several %.

Furthermore, in the present specification, a “thickness direction” of the substrate refers to a direction perpendicular to a principal surface of the substrate. The thickness direction is the same as a stacking direction of the semiconductor layers, and is also referred to as “vertical direction”. Furthermore, a direction parallel to the principal surface of the substrate may be referred to as “horizontal direction”. The “vertical” semiconductor device means a device in which a main path of a current such as a drain current or a forward current is vertical, that is, a device in which a main current passes through the substrate in the vertical direction. A “horizontal” semiconductor device means a device in which the main path of a current such as a drain current or a forward current is horizontal, that is, a device in which the main current does not pass through the substrate.

Furthermore, a side on which a heterostructure that generates the 2DEG is provided with respect to the substrate is regarded as “above” or “upper side”, and the opposite side is regarded as “below” or “lower side”. Note that, in the present specification, the terms “above” and “below” do not refer to an upward direction (vertically upward) and a downward direction (vertically downward) in absolute space recognition, but are used as terms defined by a relative positional relationship based on a stacking order in a stacking configuration. Furthermore, the terms “above” and “below” are not only applied to a case where two constituent elements are spaced apart from each other and another constituent element is present between the two constituent elements, but are also applied to a case where two constituent elements are disposed in close contact with each other and are adjacent to each other.

Furthermore, in the present specification, unless otherwise specified, “plan view” refers to when viewed from a direction perpendicular to the principal surface of the substrate of the semiconductor device, that is, when the principal surface of the substrate is viewed from the front.

Furthermore, in the present specification, “A and B overlap in plan view” means that at least a part of A and at least a part of B overlap. That is, a case where only a part of A and only a part of B overlap, a case where all of A overlap B, a case where all of B overlap A, and a case where A and B completely overlap each other are included.

Furthermore, the n-type and the p-type indicate the conductivity types of the semiconductor, and are conductivity types having opposite polarities to each other. The n⁺-type represents a state in which an n-type dopant is added to a semiconductor at a high concentration, that is, a so-called heavy dope. Furthermore, the n⁻-type represents a state in which an n-type dopant is added to a semiconductor at a low concentration, that is, so-called light doping. Both the n⁺-type and the n⁻-type are examples of the n-type, and the n⁺-type and the n⁻-type may be described as the n-type without being distinguished from each other. Furthermore, the same applies to the p-type, the p⁺-type, and the p⁻-type.

Furthermore, in the present specification, the “main component” means a component having the highest content rate among all the components constituting a member. For example, a component having a content rate of more than or equal to 50%e is a main component. The component is a material, an element, a compound, or the like.

Furthermore, in the present specification, AlGaN represents ternary mixed crystal AlₓGa₁₋ₓN (0 < x < 1). Hereinafter, a multicomponent mixed crystal is abbreviated as an arrangement of constituent element symbols, such as AlInN, GaInN, or the like. For example, AlₓGa_{1-x-y}In_{y}N (0 < x < 1, 0 < y < 1, and 0 < x + y < 1), which is an example of a nitride semiconductor, is abbreviated as AlGaInN. x, 1 - x - y, and y represent composition ratios of Al, Ga, and In, respectively.

Furthermore, in the present specification, ordinal numbers such as “first” and “second” do not mean the number or order of constituent elements unless otherwise specified, and are used for the purpose of avoiding confusion and distinguishing the same kind of constituent elements.

### First exemplary embodiment

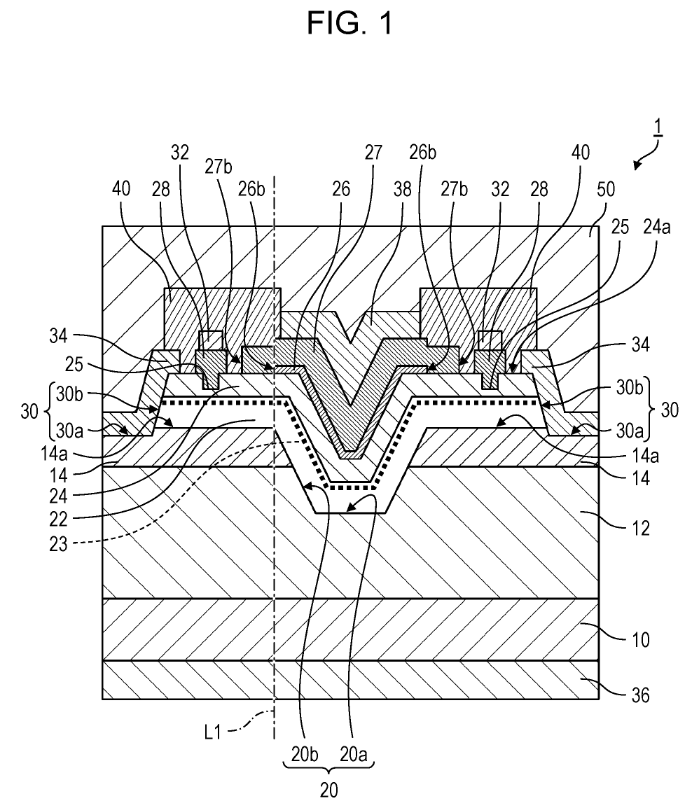

First, a configuration of a nitride semiconductor device according to a first exemplary embodiment will be described with reference to FIG. 1.

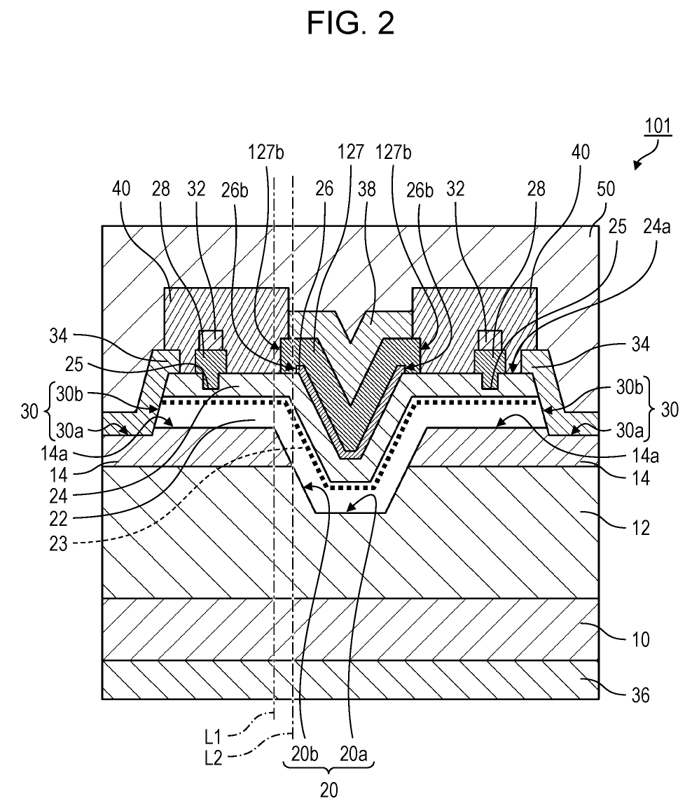

FIG. 1 is a cross-sectional view of nitride semiconductor device 1 according to the present exemplary embodiment. In FIG. 1, each constituent element such as a semiconductor layer, an insulating layer, and an electrode included in nitride semiconductor device 1 is shaded with diagonal lines representing the cross section. Note that, for electron transport layer 22, the shading of diagonal lines representing cross sections is omitted. The same applies to other cross-sectional views from FIG. 2 onwards.

Nitride semiconductor device 1 illustrated in FIG. 1 is a normally-off type vertical field effect transistor (FET). In nitride semiconductor device 1, for example, source electrode 34 is grounded, and a positive potential is applied to drain electrode 36. The potential applied to drain electrode 36 is, for example, from 100 V to 1200 V inclusive, but is not limited thereto. Nitride semiconductor device 1 performs a modulation operation according to the potential applied to gate electrode 32. For example, in a case where 0 V or a negative potential (for example, -5 V) is applied to gate electrode 32, no current flows between drain electrode 36 and source electrode 34. That is, nitride semiconductor device 1 goes into a non-conductive state (off). When a positive potential (for example, +5 V) is applied to gate electrode 32, a current flows from drain electrode 36 to source electrode 34. That is, nitride semiconductor device 1 is brought into a conductive state (on). The current flowing from drain electrode 36 to source electrode 34 when on is referred to as drain current. The drain current flows through substrate 10 in a thickness direction (that is, in a vertical direction).

As illustrated in FIG. 1, nitride semiconductor device 1 includes substrate 10, drift layer 12, block layer 14, electron transport layer 22, electron supply layer 24, intermediate layer 26, shielding layer 27, threshold value adjustment layer 28, gate electrode 32, source electrode 34, drain electrode 36, and shielding electrode 38. Nitride semiconductor device 1 further includes insulating film 40 and source wiring 50. Nitride semiconductor device 1 is provided with first opening 20 and second opening 30. Note that threshold value adjustment layer 28, gate electrode 32, second opening 30, and source electrode 34 are provided on both left and right sides of first opening 20 in a cross-sectional view illustrated in FIG. 1.

Nitride semiconductor device 1 is a device in which a semiconductor layer including a channel includes a nitride semiconductor as a main component. Specifically, each of drift layer 12, block layer 14, electron transport layer 22, electron supply layer 24, intermediate layer 26, shielding layer 27, and threshold value adjustment layer 28 includes a nitride semiconductor as a main component.

Hereinafter, details of each constituent element included in nitride semiconductor device 1 will be described.

Substrate 10 is, for example, a substrate including n⁺-type GaN having a thickness of 300 μm and a carrier concentration of 5 × 10¹⁸ cm⁻³ as a main component.

Note that substrate 10 may not be a nitride semiconductor substrate. For example, substrate 10 may be a Si substrate, a SiC substrate, a ZnO substrate, or the like.

Drift layer 12 is an example of an n-type first nitride semiconductor layer, and is provided above substrate 10. Drift layer 12 is, for example, a film including n⁻-type GaN having a thickness of 8 μm as a main component. A donor concentration of drift layer 12 is, for example, from 1 × 10¹⁵ cm⁻³ to 1 × 10¹⁷ cm⁻³ inclusive, and is, as an example, 1 × 10¹⁶ cm⁻³. Furthermore, the carbon concentration (C concentration) of drift layer 12 is, for example, from 1 × 10¹⁵ cm⁻³ to 5 × 10¹⁶ cm⁻³ inclusive. Drift layer 12 is provided, for example, in contact with an upper surface (principal surface) of substrate 10.

Block layer 14 is an example of a p-type second nitride semiconductor layer, and is provided above drift layer 12. Block layer 14 is, for example, a film including, as a main component, p-type GaN having a thickness of 400 nm and a carrier concentration of 1 × 10¹⁷ cm⁻³. Block layer 14 is provided in contact with an upper surface of drift layer 12.

Block layer 14 is provided with first opening 20. First opening 20 penetrates block layer 14 to reach drift layer 12. First opening 20 may be referred to as a gate opening or a vertical conduction opening. Bottom surface 20a of first opening 20 is a part of the upper surface of drift layer 12. As illustrated in FIG. 1, bottom surface 20a is located on a lower side than a lower surface of block layer 14. Note that the lower surface of block layer 14 corresponds to an interface between block layer 14 and drift layer 12. Bottom surface 20a is, for example, parallel to the principal surface of substrate 10. When nitride semiconductor device 1 is on, a drain current flows between drain electrode 36 and source electrode 34 through bottom surface 20a of this first opening 20.

In the present exemplary embodiment, first opening 20 is formed such that an opening area increases with increasing distance from substrate 10. Specifically, side surface 20b of first opening 20 is inclined obliquely. As illustrated in FIG. 1, the cross-sectional view shape of first opening 20 is an inverted trapezoid, more specifically, an inverted isosceles trapezoid.

An inclination angle of side surface 20b with respect to bottom surface 20a is, for example, from 20° to 80° inclusive, but may be from 30° to 45° inclusive. Since side surface 20b approaches a c-plane as the inclination angle decreases, the film quality of electron transport layer 22 and the like formed along side surface 20b by crystal regrowth can be improved. On the other hand, as the inclination angle is larger, first opening 20 is suppressed from becoming too large, and miniaturization of nitride semiconductor device 1 is realized. Note that side surface 20b may be perpendicular to bottom surface 20a.

Electron transport layer 22 is provided above substrate 10. Specifically, electron transport layer 22 is also an example of a first regrowth layer, and is provided so as to cover an inner surface of first opening 20 and above block layer 14. For example, a part of electron transport layer 22 is provided along bottom surface 20a and side surface 20b of first opening 20, and the other part of electron transport layer 22 is provided on upper surface 14a of block layer 14. A thickness of electron transport layer 22 is, for example, from 50 nm to 300 nm inclusive. Electron transport layer 22 is, for example, a film including undoped GaN having a thickness of 150 nm as a main component. Note that the thickness of electron transport layer 22 is regarded as a thickness on an outer side of first opening 20 in plan view of substrate 10, that is, at a flat portion that is a portion overlapping upper surface 14a of block layer 14. Furthermore, electron transport layer 22 is assumed to be undoped, but may be partially made into an n-type by Si doping or the like.

Electron transport layer 22 is in contact with drift layer 12 on bottom surface 20a and side surface 20b of first opening 20. Furthermore, electron transport layer 22 is in contact with block layer 14 on side surface 20b of first opening 20. Moreover, electron transport layer 22 is in contact with upper surface 14a of block layer 14.

Electron transport layer 22 includes a channel. Specifically, 2DEG 23 serving as a channel is generated in the vicinity of an interface between electron transport layer 22 and electron supply layer 24. 2DEG 23 is bent along the interface between electron transport layer 22 and electron supply layer 24, that is, along the inner surface of first opening 20.

Although not illustrated in FIG. 1, an AlN layer having a thickness of about 1 nm is provided as a second regrowth layer between electron transport layer 22 and electron supply layer 24. As a result, alloy scattering is suppressed, channel mobility is improved, and on-resistance can be reduced. Note that the AlN layer is not necessarily required.

Electron supply layer 24 is provided above electron transport layer 22. Specifically, electron supply layer 24 is also an example of a third regrowth layer, and is provided so as to cover the inner surface of first opening 20 and above block layer 14. Specifically, electron supply layer 24 is provided along an upper surface of electron transport layer 22 so as to overlap bottom surface 20a and side surface 20b of first opening 20 and upper surface 14a of block layer 14 in plan view of substrate 10.

Electron supply layer 24 has a band gap larger than that of electron transport layer 22. Therefore, an AlGaN/GaN hetero interface is formed between electron supply layer 24 and electron transport layer 22. Electron supply layer 24 supplies electrons to the channel (2DEG 23) formed in electron transport layer 22.

Electron supply layer 24 is, for example, a film including undoped AlGaN as a main component. Electron supply layer 24 is formed in a shape along the upper surface of electron transport layer 22 and has a substantially uniform thickness. Note that a thickness of electron supply layer 24 is regarded as a thickness on the outer side of first opening 20 in plan view of substrate 10, that is, at a flat portion that is the portion overlapping upper surface 14a of block layer 14.

Note that, in a case where electron supply layer 24 includes AlGaN having an Al composition ratio of 20% as a main component, cracks are likely to occur when the thickness of electron supply layer 24 exceeds 70 nm. For this reason, the film quality of electron supply layer 24 is deteriorated, which may cause leakage, or 2DEG 23 may not be generated at a desired concentration. In a case where the Al composition ratio is lowered, generation of cracks can be suppressed, so that the thickness of electron supply layer 24 can be set to, for example, from 10 nm to 150 nm inclusive. The Al composition ratio of electron supply layer 24 is not particularly limited, but is, for example, from 10% to 30% inclusive.

Electron supply layer 24 is provided with recess 25. Recess 25 is provided at a position overlapping upper surface 14a of block layer 14 in plan view of substrate 10. Recess 25 is a concave portion recessed from upper surface 24a of electron supply layer 24 toward substrate 10. A side surface of recess 25 is perpendicular to a bottom surface of recess 25, but may be inclined obliquely.

Intermediate layer 26 is provided at a position overlapping first opening 20 in plan view of substrate 10 between electron supply layer 24 and shielding layer 27. Specifically, intermediate layer 26 is provided in contact with each of upper surface 24a of electron supply layer 24 and a lower surface of shielding layer 27. In the present exemplary embodiment, side surface 26b of intermediate layer 26 is covered with shielding layer 27. That is, side surface 26b is covered in contact with shielding layer 27. Furthermore, intermediate layer 26 is provided at a position overlapping bottom surface 20a and side surface 20b of first opening 20 in plan view of substrate 10. In FIG. 1, straight line L1, which is a straight line passing through an upper end of first opening 20 and is orthogonal to the principal surface of substrate 10, is represented by a one-dot chain line. A part of intermediate layer 26 may be provided on a source electrode 34 side beyond straight line L1. That is, a part of intermediate layer 26 may overlap the outside of first opening 20, that is, upper surface 14a of block layer 14 in plan view of substrate 10. An end portion of intermediate layer 26 on the source electrode 34 side may overlap upper surface 14a of block layer 14 in plan view of substrate 10. Intermediate layer 26 is formed in a shape along upper surface 24a of electron supply layer 24 and has a substantially uniform thickness.

Intermediate layer 26 includes a nitride semiconductor as a main component. In the present exemplary embodiment, the conductivity type of intermediate layer 26 is n-type. Specifically, intermediate layer 26 is a film including n-type GaN as a main component. The carrier concentration of intermediate layer 26 is, for example, more than or equal to 2 × 10¹⁷ cm⁻³. As a result, the concentration of 2DEG 23 can be increased. The carrier concentration of intermediate layer 26 may be, for example, less than or equal to 1 × 10²⁰ cm⁻³. The concentration of 2DEG 23 is substantially saturated when the carrier concentration of intermediate layer 26 is in a range of more than or equal to 5 × 10¹⁸ cm⁻³.

A film thickness of intermediate layer 26 is, for example, from 20 nm to 500 nm inclusive, and is 22 nm as an example. Since the concentration of 2DEG 23 rapidly increases when the film thickness of intermediate layer 26 is in a range from 20 nm to 50 nm inclusive, the effect of reducing the on-resistance is high. On the other hand, the concentration of 2DEG 23 is substantially saturated in a range where the film thickness of intermediate layer 26 is from 100 nm to 500 nm inclusive. Therefore, it is possible to suppress intermediate layer 26 from being thickened more than necessary, and it is possible to suppress the occurrence of step disconnection of shielding layer 27 and shielding electrode 38 formed above. Furthermore, the time required for film deposition of intermediate layer 26 can be shortened.

Shielding layer 27 is an example of a shielding portion included in a p-type third nitride semiconductor layer, and is provided above electron supply layer 24. Shielding layer 27 overlaps first opening 20 in plan view of substrate 10 and is electrically connected to shielding electrode 38. As illustrated in FIG. 1, shielding layer 27 is provided so as to protrude from intermediate layer 26 toward source electrode 34 in plan view of substrate 10. Shielding layer 27 covers side surface 26b of intermediate layer 26. Specifically, shielding layer 27 is provided so as to contact and cover the upper surface and side surface 26b of intermediate layer 26 and upper surface 24a of electron supply layer 24. An end portion of shielding layer 27 on the source electrode 34 side, that is, side surface 27b overlaps upper surface 14a of block layer 14 in plan view of substrate 10. That is, a part of shielding layer 27 is provided on the source electrode 34 side beyond straight line L1.

Shielding layer 27 is, for example, a film including, as a main component, p-type GaN having a thickness of 50 nm and a carrier concentration of 5 × 10¹⁷ cm⁻³. A thickness of shielding layer 27 is, for example, from 100 nm to 500 nm inclusive. Note that the thickness and the carrier concentration of shielding layer 27 are merely examples, and can be appropriately changed. For example, shielding layer 27 may be a film including p-type AlGaN as a main component.

Threshold value adjustment layer 28 is an example of a gate portion included in the p-type third nitride semiconductor layer, and is provided above electron supply layer 24. Threshold value adjustment layer 28 overlaps upper surface 14a of block layer 14 in plan view of substrate 10, and is electrically connected to gate electrode 32. Threshold value adjustment layer 28 does not overlap first opening 20 in plan view of substrate 10. Threshold value adjustment layer 28 is provided separately from shielding layer 27 and is electrically separated.

Threshold value adjustment layer 28 is provided in contact with at least a part of a bottom surface of recess 25. In the present exemplary embodiment, threshold value adjustment layer 28 is provided so as to cover recess 25. A length of threshold value adjustment layer 28 in a gate length direction is longer than a length of recess 25 in the gate length direction. Threshold value adjustment layer 28 is also provided outside recess 25.

Threshold value adjustment layer 28 can be formed in the same process as shielding layer 27. Therefore, the main component, composition, carrier concentration, and the like of threshold value adjustment layer 28 are the same as those of shielding layer 27. For example, threshold value adjustment layer 28 is a film including, as a main component, p-type GaN having a thickness of 50 nm and a carrier concentration of 5 × 10¹⁷ cm⁻³. Note that the thickness and carrier concentration of threshold value adjustment layer 28 are merely examples, and can be changed as appropriate. For example, threshold value adjustment layer 28 may be a film including p-type AlGaN as a main component. Shielding layer 27 and threshold value adjustment layer 28 may be different from each other in at least one of a thickness, a composition, and a carrier concentration.

In a portion where recess 25 is provided, the thickness of electron supply layer 24 becomes thin. As illustrated in FIG. 1, a thickness of the portion of the electron supply layer 24 where the recess 25 is provided is thinner than a thickness of a portion where the recess 25 is not provided. As the thickness of the portion where recess 25 is provided decreases, the concentration of 2DEG 23 in a direction immediately below recess 25 decreases. Therefore, a threshold value of the transistor can be increased. For example, the threshold value can be made higher than 0 V, which facilitates normally-off of the transistor. The threshold value of the transistor can be determined by adjusting a size of the thickness of the portion provided with recess 25. For example, the thickness of the portion where recess 25 is provided is from 10 nm to 60 nm inclusive, and is, as an example, 22 nm.

Furthermore, a portion of electron supply layer 24 where recess 25 is not provided can be thickened without affecting the threshold value of the transistor. Therefore, the concentration of 2DEG 23 in the direction immediately below the portion where recess 25 is not provided increases, so that the on-resistance can be reduced. For example, the thickness of the portion where the recess is not provided is from 10 nm to 70 nm inclusive, and is, as an example, 60 nm. By providing recess 25 in this manner, it is possible to achieve both the normally-off and the reduction of the on-resistance.

Second opening 30 penetrates electron supply layer 24 and electron transport layer 22 and reaches block layer 14. Second opening 30 may be referred to as source opening. Second opening 30 is provided at a position apart from both gate electrode 32 and threshold value adjustment layer 28 in plan view of substrate 10. Since second opening 30 penetrates electron transport layer 22, 2DEG 23 is exposed on side surface 30b of second opening 30.

Bottom surface 30a of the second opening 30 is a part of upper surface 14a of block layer 14. Bottom surface 30a is, for example, parallel to the principal surface of substrate 10. In the example illustrated in FIG. 1, bottom surface 30a is located on a lower side than a lower surface of electron transport layer 22. Note that the lower surface of electron transport layer 22 corresponds to an interface between electron transport layer 22 and block layer 14.

Furthermore, as illustrated in FIG. 1, second opening 30 is formed such that an opening area increases as a distance from substrate 10 increases. Specifically, side surface 30b of second opening 30 is inclined obliquely. At this time, an inclination angle of side surface 30b with respect to bottom surface 30a is, for example, in a range from 30° to 60° inclusive. Since side surface 30b is inclined obliquely, a contact area between source electrode 34 and 2DEG 23 increases, so that ohmic connection is easily performed. Note that 2DEG 23 is exposed to side surface 30b of second opening 30, and is connected to source electrode 34 at an exposed portion. Furthermore, side surface 30b may be perpendicular to bottom surface 30a.

Since second opening 30 is provided, ohmic contact resistance between 2DEG 23 functioning as a channel and source electrode 34 can be reduced. That is, the on-resistance of nitride semiconductor device 1 can be reduced.

Furthermore, source electrode 34 and block layer 14 are electrically connected to each other at bottom surface 30a of second opening 30. As a result, the same potential as a potential applied to source electrode 34 is supplied to block layer 14. In a case where a reverse voltage is applied to the pn junction formed by block layer 14 and drift layer 12, specifically, in a case where drain electrode 36 has a higher potential than source electrode 34, a depletion layer extends to drift layer 12, so that the withstand voltage of nitride semiconductor device 1 can be increased.

Gate electrode 32 is provided above threshold value adjustment layer 28. Specifically, gate electrode 32 is provided in contact with an upper surface of threshold value adjustment layer 28, and is electrically connected to threshold value adjustment layer 28. Gate electrode 32 is provided at a position overlapping block layer 14 without overlapping first opening 20 in plan view of substrate 10. Specifically, gate electrode 32 overlaps upper surface 14a of block layer 14 in plan view of substrate 10.

Gate electrode 32 is formed using, for example, a conductive material such as metal. For example, gate electrode 32 may be made of a material such as p-type GaN which is ohmic-connected to a p-type nitride semiconductor, but is not limited thereto, and may be made of a material which is Schottky connected to a p-type nitride semiconductor. For example, Pd, a Ni-based material, WSi, Au, or the like can be used as a material for forming gate electrode 32.

Source electrode 34 is provided above block layer 14 and apart from gate electrode 32. In the present exemplary embodiment, source electrode 34 is electrically connected to block layer 14 via second opening 30. Furthermore, source electrode 34 is electrically connected to electron transport layer 22 via second opening 30. Specifically, source electrode 34 is provided in contact with bottom surface 30a and side surface 30b of second opening 30. Source electrode 34 is in contact with block layer 14 at bottom surface 30a of second opening 30. Source electrode 34 is in contact with 2DEG 23 on side surface 30b of second opening 30. As a result, the contact resistance between source electrode 34 and 2DEG 23 can be reduced, so that the on-resistance of nitride semiconductor device 1 can be reduced.

Source electrode 34 is formed using a conductive material such as metal. As a material of source electrode 34, for example, a material that is ohmic-connected to an n- type nitride semiconductor such as n-type GaN by heat treatment, such as Ti/Al (stacked structure of Ti layer and Al layer), can be used.

Drain electrode 36 is provided below substrate 10. Specifically, drain electrode 36 is provided in contact with the lower surface of substrate 10.

Drain electrode 36 is formed using a conductive material such as metal. As the material of drain electrode 36, similarly to the material of source electrode 34, for example, a material such as Ti/Al that is ohmic-connected to an n-type nitride semiconductor such as n-type GaN can be used.

Shielding electrode 38 is provided above shielding layer 27 at a position overlapping first opening 20 in plan view of substrate 10. Shielding electrode 38 is electrically connected to source electrode 34 and shielding layer 27. Specifically, source wiring 50 is connected to shielding electrode 38, and is set to the same potential as source electrode 34.

Gate electrode 32 and shielding electrode 38 are formed by removing and separating a part of the conductive film formed in the same process. Therefore, the main components of gate electrode 32 and shielding electrode 38 are the same. For example, each of gate electrode 32 and shielding electrode 38 includes, as a main component, a material that is ohmic-connected to a p-type nitride semiconductor such as p-type GaN. For example, Pd, a Ni-based material, WSi, Au, or the like can be used as a material for forming gate electrode 32 and shielding electrode 38.

Insulating film 40 is provided above gate electrode 32. Specifically, insulating film 40 is provided so as to cover gate electrode 32, shielding layer 27, threshold value adjustment layer 28, electron supply layer 24, and source electrode 34. Insulating film 40 has a stacked structure of a plurality of insulating films. The plurality of insulating films is, for example, insulating films of SiN, SiO₂, SiON, Al₂O₃, or the like. Note that insulating film 40 may have a single-layer structure of one insulating film.

Source wiring 50 is provided above insulating film 40, and is connected to source electrode 34 and shielding electrode 38 via an opening provided in insulating film 40. Source wiring 50 is formed using a conductive material such as metal. For example, source wiring 50 is a plated film made of Au, for example.

In nitride semiconductor device 1 configured as described above, 2DEG 23 is generated in the vicinity of the interface between electron transport layer 22 and electron supply layer 24, and can be used as a channel. In a region overlapping p-type threshold value adjustment layer 28 in plan view, the potential of the conduction band edge of the channel can be increased. Therefore, nitride semiconductor device 1 can be operated as a normally-off transistor.

Furthermore, according to nitride semiconductor device 1 of the present exemplary embodiment, the threshold value of the transistor is determined by the flat portion of the channel outside first opening 20, and is not affected by the inclined portion of the channel. Therefore, controllability of on and off of the transistor can be enhanced. Furthermore, by providing shielding electrode 38 electrically connected to source electrode 34, shielding electrode 38 can terminate the line of electric force extending from drain electrode 36. Parasitic capacitance Cgd between the gate and the drain can be reduced, and the switching speed can be increased.

Furthermore, a source potential is supplied from shielding electrode 38 to shielding layer 27. Therefore, a reverse bias can be applied to the pn junction between shielding layer 27 and 2DEG 23 via shielding electrode 38 and drain electrode 36. Therefore, the withstand voltage of the transistor can be increased. Moreover, in a region overlapping p-type shielding layer 27 in plan view, the influence of p-type shielding layer 27 on the channel can be suppressed by intermediate layer 26. That is, a decrease in the concentration of 2DEG 23 can be suppressed, and the on-resistance can be reduced.

As described above, intermediate layer 26 is provided for the purpose of reducing the on-resistance, but side surface 26b of intermediate layer 26 may be damaged by plasma when insulating film 40 is formed. For this reason, a leak current path may be formed at the pn junction interface between p-type shielding layer 27 and n-type intermediate layer 26, and the leak current may increase. On the other hand, in nitride semiconductor device 1 according to the present exemplary embodiment, side surface 26b of intermediate layer 26 is covered with shielding layer 27. Since the pn junction interface is not exposed at the time of forming insulating film 40, a leak current path is hardly formed, and the leak current can be reduced.

A manufacturing method of nitride semiconductor device 1 is not particularly limited, but for example, the following manufacturing method can be used.

First, a nitride semiconductor is crystal-grown by epitaxial growth on the principal surface of substrate 10 to form a plurality of nitride semiconductor films. Specifically, drift layer 12 and block layer 14 are formed in this order on the principal surface of substrate 10. In the epitaxial growth, the composition, thickness, conductivity type, impurity concentration, and the like of each of the nitride semiconductor films can be adjusted by adjusting growth conditions such as a raw material, a growth temperature, and a growth time.

Thereafter, a part of block layer 14 is removed to form first opening 20. For example, block layer 14 is removed by photolithography, dry etching, or the like. At this time, by removing a part of a surface layer portion of drift layer 12 continuously from the removal of block layer 14, bottom surface 20a of first opening 20 is formed below the interface between block layer 14 and drift layer 12 as illustrated in FIG. 1.

Next, a nitride semiconductor is crystal-grown by the second epitaxial growth so as to cover bottom surface 20a and side surface 20b of first opening 20 and upper surface 14a of block layer 14. Specifically, electron transport layer 22, electron supply layer 24, and intermediate layer 26 are formed in this order.

Next, second opening 30 is formed by removing a part of each of intermediate layer 26, electron supply layer 24, and electron transport layer 22. For example, each layer is removed by photolithography, dry etching, or the like. At this time, by removing a part of a surface layer portion of block layer 14 continuously from the removal of electron transport layer 22, bottom surface 30a of second opening 30 is formed below the interface between block layer 14 and electron transport layer 22 as illustrated in FIG. 1. Moreover, by removing a part of intermediate layer 26, intermediate layer 26 is patterned into a predetermined shape. As a result, a part of upper surface 24a of electron supply layer 24 is exposed without being covered with intermediate layer 26. Moreover, recess 25 is formed by removing a part of electron supply layer 24.

Next, a nitride semiconductor is crystal-grown by the third epitaxial growth so as to cover intermediate layer 26 and recess 25. Specifically, a nitride semiconductor film is formed so as to cover intermediate layer 26 and recess 25, and then a part of the formed nitride semiconductor film is removed to form shielding layer 27 and threshold value adjustment layer 28. At this time, shielding layer 27 remains covering side surface 26b of intermediate layer 26. That is, a part of shielding layer 27 is formed so as to protrude from intermediate layer 26 toward source electrode 34. Note that shielding layer 27 and threshold value adjustment layer 28 may be formed in different processes. As a result, the compositions, impurity concentrations, and the like of shielding layer 27 and threshold value adjustment layer 28 can be made different. Furthermore, the threshold value adjustment layer 28 may not be formed.

Next, gate electrode 32, shielding electrode 38, and source electrode 34 are formed. For example, first, a conductive film is formed using a conductive material ohmic-connected to an n-type nitride semiconductor, and then patterned into a predetermined shape to form source electrode 34. The conductive film is formed by sputtering or vapor deposition. Patterning of the conductive film is performed by etching, a lift-off method, or the like. Source electrode 34 is formed so as to contact and cover bottom surface 30a and side surface 30b of second opening 30 and not to contact threshold value adjustment layer 28. Next, a conductive film is formed using a conductive material ohmic-connected to a p-type nitride semiconductor, and then patterned into a predetermined shape to form gate electrode 32 and shielding electrode 38. Formation and patterning of the conductive film are the same as in the case of source electrode 34. Gate electrode 32 is formed on the upper surface of threshold value adjustment layer 28 so as not to contact upper surface 24a of electron supply layer 24, source electrode 34, and shielding layer 27. Furthermore, shielding electrode 38 is formed on the upper surface of shielding layer 27 so as not to contact upper surface 24a of electron supply layer 24 and threshold value adjustment layer 28.

Note that gate electrode 32 and shielding electrode 38 may be formed in different processes. The formation of gate electrode 32 and shielding electrode 38 may be performed before the formation of source electrode 34. Furthermore, for example, after gate electrode 32 is patterned, threshold value adjustment layer 28 may be patterned using gate electrode 32 as a mask. Furthermore, in a case where gate electrode 32, shielding electrode 38, and source electrode 34 are formed using the same conductive material, gate electrode 32, shielding electrode 38, and source electrode 34 may be formed in the same process.

Next, insulating film 40 and source wiring 50 are formed. Insulating film 40 is formed by a plasma chemical vapor deposition (CVD) method, an atomic layer deposition (ALD) method, a coating method, or the like. Source electrode 34 is exposed by etching insulating film 40 after the film deposition. Thereafter, source wiring 50 is formed by a plating method or the like. Note that, although not illustrated in FIG. 1, the gate wiring electrically connected to gate electrode 32 can also be formed in the same manner as source wiring 50.

Next, drain electrode 36 is formed on the lower surface of substrate 10. For example, drain electrode 36 is formed by forming a conductive film using a conductive material ohmic-connected to an n-type nitride semiconductor. The conductive film is formed by sputtering or vapor deposition.

Through the above processes, nitride semiconductor device 1 illustrated in FIG. 1 can be manufactured.

### Second exemplary embodiment

Subsequently, a second exemplary embodiment will be described.

The second exemplary embodiment is different from the first exemplary embodiment mainly in the shape of a shielding layer. Hereinafter, differences from the first exemplary embodiment will be mainly described, and description of common points will be omitted or simplified.

FIG. 2 is a cross-sectional view of nitride semiconductor device 101 according to the present exemplary embodiment. Nitride semiconductor device 101 illustrated in FIG. 2 includes shielding layer 127 instead of shielding layer 27 as compared with nitride semiconductor device 1 illustrated in FIG. 1.

Shielding layer 127 has the same configuration as shielding layer 27, and has a different cross-sectional shape. Specifically, an end portion of shielding layer 127 on a source electrode 34 side overlaps inclined side surface 20b of first opening 20 in plan view of substrate 10. The end portion of shielding layer 127 on the source electrode 34 side is side surface 127b illustrated in FIG. 2. FIG. 2 illustrates straight line L2 that passes through a lower end of block layer 14 in side surface 20b of first opening 20 and is perpendicular to a principal surface of substrate 10. Side surface 127b of shielding layer 127 is located between straight line L1 and straight line L2. Note that, similarly to the first exemplary embodiment, straight line L1 is a straight line passing through the upper end of first opening 20 and orthogonal to the principal surface of substrate 10.

According to the present exemplary embodiment, an area in which shielding layer 127 is in contact with electron supply layer 24 without interposing intermediate layer 26 is reduced. That is, an area of a non-overlapping portion of shielding layer 127 that does not overlap intermediate layer 26 in plan view is reduced. Therefore, a decrease in the concentration of 2DEG 23 can be suppressed, and the on-resistance can be reduced.

Note that, as side surface 127b of shielding layer 127 approaches bottom surface 20a of first opening 20 in plan view, the overlapping between block layer 14 and shielding layer 127 decreases, so that parasitic capacitance Cgd between the gate and the drain may decrease. Side surface 127b of shielding layer 127 can be located at an appropriate position in view of the effect of reducing the on-resistance and the magnitude of parasitic capacitance Cgd.

### Third exemplary embodiment

Subsequently, a third exemplary embodiment will be described.

The third exemplary embodiment is mainly different from the first exemplary embodiment in that a side surface of an intermediate layer is covered with a threshold value adjustment layer. Hereinafter, differences from the first exemplary embodiment will be mainly described, and description of common points will be omitted or simplified.

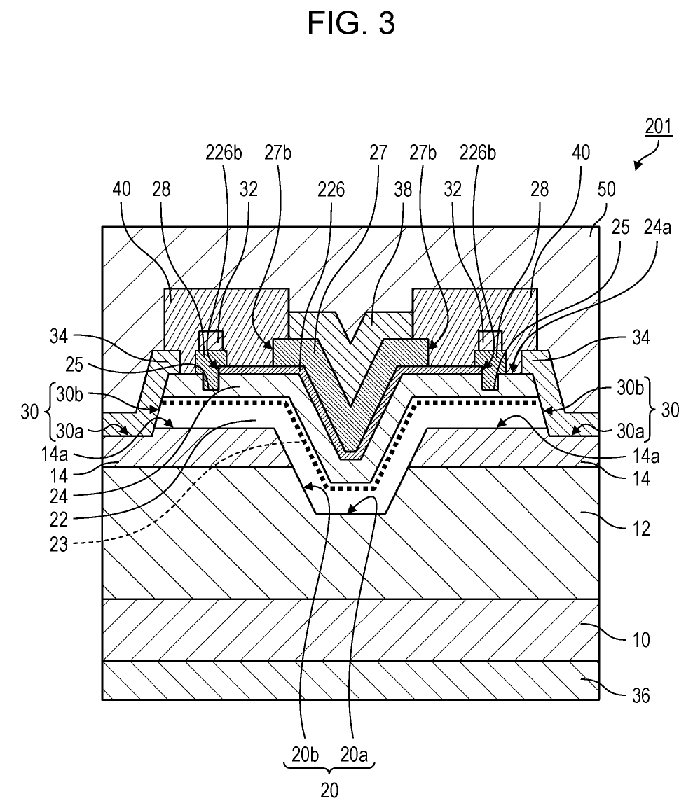

FIG. 3 is a cross-sectional view of nitride semiconductor device 201 according to the present exemplary embodiment. Nitride semiconductor device 201 illustrated in FIG. 3 includes intermediate layer 226 instead of intermediate layer 26 as compared with nitride semiconductor device 1 illustrated in FIG. 1.

Intermediate layer 226 has the same configuration as intermediate layer 26, and has a different cross-sectional shape. Intermediate layer 226 is provided between electron supply layer 24, and shielding layer 27 and threshold value adjustment layer 28. That is, a part of intermediate layer 226 overlaps threshold value adjustment layer 28 in plan view of substrate 10. Specifically, an end portion of intermediate layer 226 on a source electrode 34 side is located between threshold value adjustment layer 28 and electron supply layer 24. Side surface 226b of intermediate layer 226 is covered with threshold value adjustment layer 28.

In the example illustrated in FIG. 3, side surface 226b of intermediate layer 226 is flush with a side surface of recess 25, but the present disclosure is not limited thereto. The side surface of recess 25 may be located closer to the side of source electrode 34 than side surface 226b of intermediate layer 226.

According to the present exemplary embodiment, since side surface 226b of intermediate layer 226 is covered with threshold value adjustment layer 28, a leak current via side surface 226b of intermediate layer 226 can be reduced. Furthermore, since an area of intermediate layer 226 increases, a decrease in the concentration of 2DEG 23 can be further suppressed, and the on-resistance can be further reduced.

### Fourth exemplary embodiment

Subsequently, a fourth exemplary embodiment will be described.

The fourth exemplary embodiment is mainly different from the third exemplary embodiment in that an intermediate layer has a stacked structure. Hereinafter, differences from the third exemplary embodiment will be mainly described, and description of common points will be omitted or simplified.

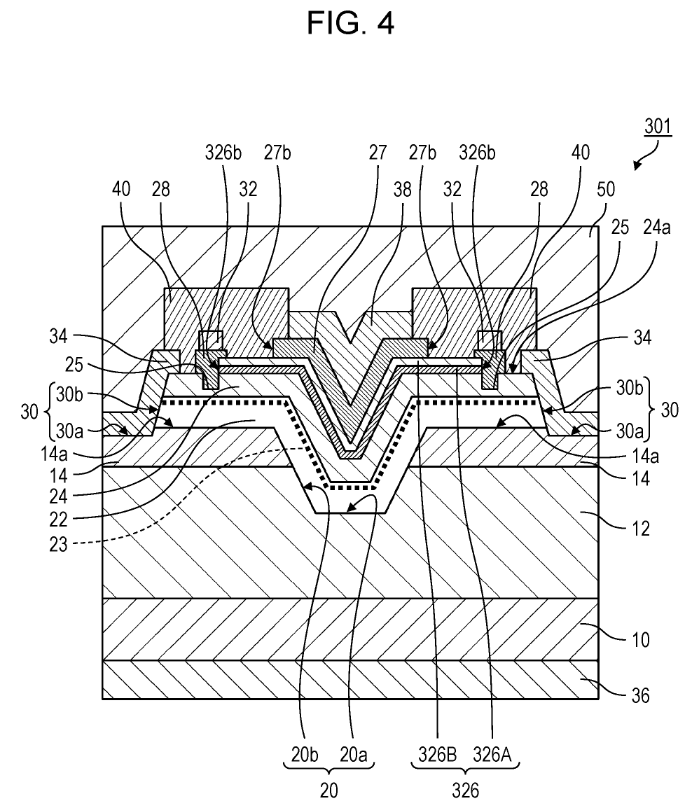

FIG. 4 is a cross-sectional view of nitride semiconductor device 301 according to the present exemplary embodiment. Nitride semiconductor device 301 illustrated in FIG. 4 includes intermediate layer 326 instead of intermediate layer 226 as compared with nitride semiconductor device 201 illustrated in FIG. 3. Intermediate layer 326 includes GaN layer 326A and AlGaN layer 326B.

GaN layer 326A is a nitride semiconductor layer including GaN as a main component. GaN layer 326A is provided between electron supply layer 24, and shielding layer 27 and threshold value adjustment layer 28. That is, a part of GaN layer 326A overlaps threshold value adjustment layer 28 in plan view of substrate 10. Specifically, an end portion of GaN layer 326A on a source electrode 34 side is located between threshold value adjustment layer 28 and electron supply layer 24.

The conductivity type of GaN layer 326A is n-type. The carrier concentration of GaN layer 326A is, for example, more than or equal to 2 × 10¹⁷ cm⁻³. As a result, the concentration of 2DEG 23 can be increased. Furthermore, the carrier concentration of GaN layer 326A may be, for example, less than or equal to 1 × 10²⁰ cm⁻³. The concentration of 2DEG 23 is substantially saturated when the carrier concentration of GaN layer 326A is in a range of more than or equal to 5 × 10¹⁸ cm⁻³.

A film thickness of GaN layer 326A is, for example, from 20 nm to 500 nm inclusive, and is, as an example, 22 nm. Since the concentration of 2DEG 23 rapidly increases when the film thickness of GaN layer 326A is in a range from 20 nm to 50 nm inclusive, the effect of reducing the on-resistance is high. On the other hand, the concentration of 2DEG 23 is substantially saturated in a range where the film thickness of GaN layer 326A is from 100 nm to 500 nm inclusive. Therefore, it is possible to suppress GaN layer 326A from being thickened more than necessary, and it is possible to suppress the occurrence of step disconnection of shielding layer 27, threshold value adjustment layer 28, gate electrode 32, and shielding electrode 38 formed above. Furthermore, the time required for film deposition of GaN layer 326A can be shortened.

AlGaN layer 326B is a nitride semiconductor layer including AlGaN as a main component, and is provided above GaN layer 326A. AlGaN layer 326B is provided between GaN layer 326A, and shielding layer 27 and threshold value adjustment layer 28. That is, a part of AlGaN layer 326B overlaps threshold value adjustment layer 28 in plan view of substrate 10. Specifically, an end portion of AlGaN layer 326B on a source electrode 34 side is located between threshold value adjustment layer 28 and GaN layer 326A.

The conductivity type of AlGaN layer 326B is n-type. Specifically, the carrier concentration of the AlGaN layer 326B is not particularly limited, but is, for example, from 2 × 10¹⁷ cm⁻³ to 1 × 10²⁰ cm⁻³ inclusive. A film thickness of AlGaN layer 326B is, for example, less than or equal to 50 nm. An Al composition ratio of AlGaN layer 326B is not particularly limited, but is, for example, from 10% to 30% inclusive.

In the present exemplary embodiment, side surface 326b of intermediate layer 326 is covered with threshold value adjustment layer 28. That is, both the side surface of GaN layer 326A and the side surface of AlGaN layer 326B are covered with threshold value adjustment layer 28. As a result, a leak current via side surface 326b of intermediate layer 326 can be reduced. Furthermore, since the upper surface of GaN layer 326A is covered with AlGaN layer 326B, the upper surface of GaN layer 326A is not in contact with threshold value adjustment layer 28 and shielding layer 27. Since the upper surface of GaN layer 326A is less likely to be damaged by plasma, a leak current can be reduced. Moreover, in nitride semiconductor device 301 according to the present exemplary embodiment, as in the third exemplary embodiment, an area of intermediate layer 326 is increased, so that a decrease in the concentration of 2DEG 23 can be further suppressed, and the on-resistance can be further reduced.

Intermediate layer 326 according to the present exemplary embodiment may be provided in nitride semiconductor devices 1 and 101 according to the first exemplary embodiment and the second exemplary embodiment, respectively. That is, the side surface of each of GaN layer 326A and AlGaN layer 326B may be covered with shielding layer 27.

### Fifth exemplary embodiment

Subsequently, a fifth exemplary embodiment will be described.

The fifth exemplary embodiment is mainly different from the first exemplary embodiment in that a recess is not provided in an electron supply layer. Hereinafter, differences from the first exemplary embodiment will be mainly described, and description of common points will be omitted or simplified.

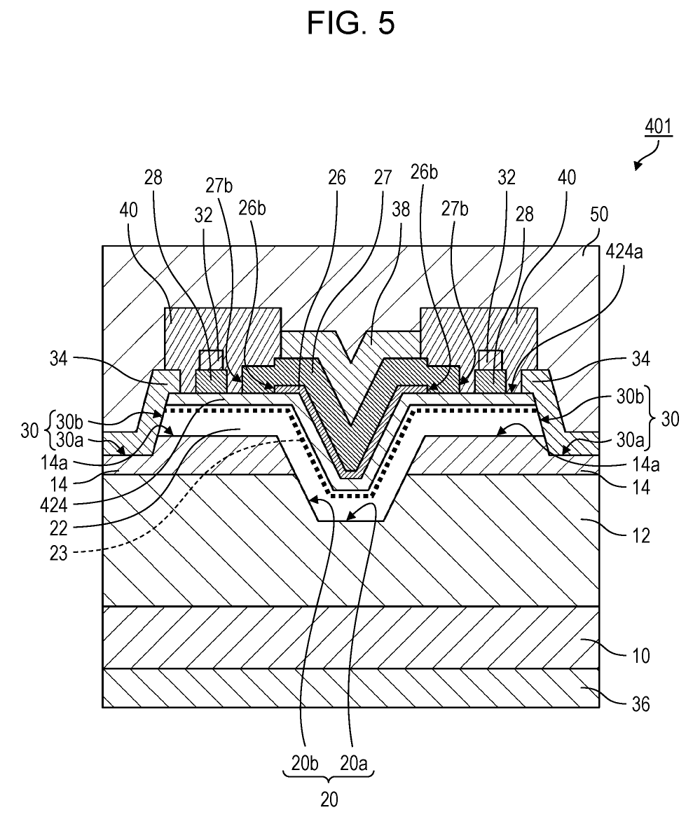

FIG. 5 is a cross-sectional view of nitride semiconductor device 401 according to the present exemplary embodiment. Nitride semiconductor device 401 illustrated in FIG. 5 includes electron supply layer 424 instead of electron supply layer 24 as compared with nitride semiconductor device 1 illustrated in FIG. 1.

Electron supply layer 424 has the same configuration as electron supply layer 24, but is not provided with recess 25. Specifically, upper surface 424a of electron supply layer 424 is a flat surface between source electrode 34 and shielding layer 27 and within a range overlapping upper surface 14a of block layer 14 in plan view of substrate 10. That is, upper surface 424a of electron supply layer 424 is flat within a range outside first opening 20 in plan view of substrate 10.

Since recess 25 is not provided, a threshold value of nitride semiconductor device 401 depends on a thickness of a portion of electron supply layer 424 overlapping threshold value adjustment layer 28 in plan view (that is, the flat portion of electron supply layer 424). In a case where the flat portion of electron supply layer 424 is too thick, the concentration of 2DEG 23 becomes too high, and it becomes difficult to set the threshold value to more than or equal to 0 V and perform normally-off. Therefore, the thickness of the flat portion of electron supply layer 424 is, for example, from 10 nm to 70 nm inclusive, and is, as an example, 22 nm. As a result, it is possible to realize normally-off of the transistor.

According to nitride semiconductor device 401, it is not necessary to form recess 25, so that stability of the process can be enhanced. By enhancing the stability of the process, the threshold value can be stabilized. Note that electron supply layer 424 not provided with recess 25 may be provided instead of electron supply layer 24 in nitride semiconductor devices 101, 201, and 301 according to the second exemplary embodiment to the fourth exemplary embodiment. Furthermore, similarly to intermediate layer 326 according to the fourth exemplary embodiment, intermediate layer 26 of nitride semiconductor device 401 may have a stacked structure of a GaN layer and an AlGaN layer.

### Sixth exemplary embodiment

Subsequently, a sixth exemplary embodiment will be described.

The sixth exemplary embodiment is mainly different from the first exemplary embodiment in that a source electrode is electrically connected to a p-type block layer via a p-type nitride semiconductor layer. Hereinafter, differences from the first exemplary embodiment will be mainly described, and description of common points will be omitted or simplified.

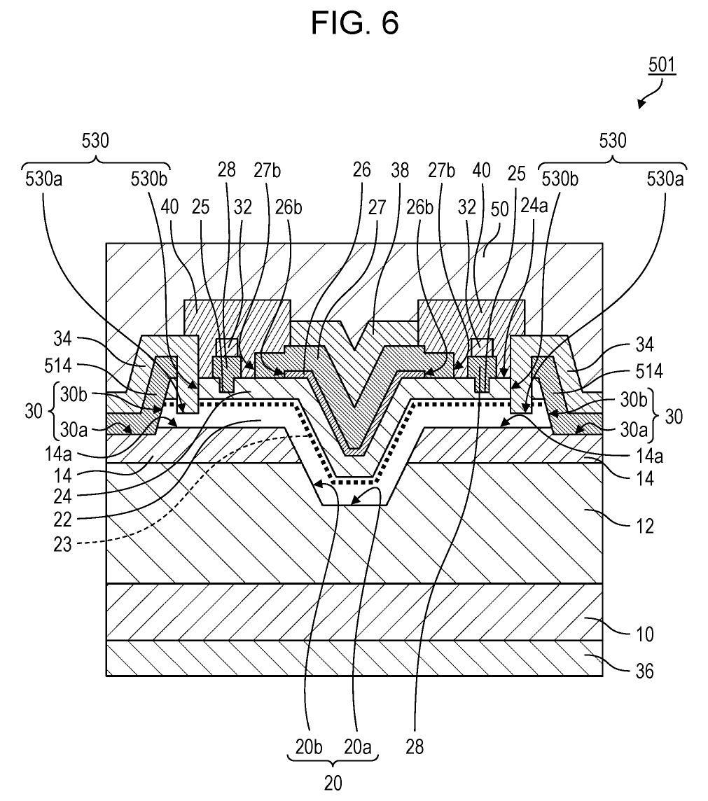

FIG. 6 is a cross-sectional view of nitride semiconductor device 501 according to the present exemplary embodiment. Nitride semiconductor device 501 illustrated in FIG. 6 includes contact layer 514 as compared with nitride semiconductor device 1 illustrated in FIG. 1. Furthermore, in nitride semiconductor device 501, third opening 530 is provided.

Contact layer 514 is an example of a p-type fourth nitride semiconductor layer, and is provided so as to be in contact with block layer 14 in second opening 30. Specifically, contact layer 514 contacts and covers bottom surface 30a and side surface 30b of second opening 30, and is in contact with block layer 14 at bottom surface 30a and a part of side surface 30b. Note that contact layer 514 may cover the vicinity of an opening end portion of second opening 30 in the upper surface of electron supply layer 24.

Contact layer 514 is a film including, as a main component, p-type GaN having a thickness of 200 nm and a carrier concentration of 5 × 10¹⁷ cm⁻³. Contact layer 514 can be formed in the same process as shielding layer 27 and threshold value adjustment layer 28. Therefore, the composition and carrier concentration of contact layer 514 are the same as those of shielding layer 27 and threshold value adjustment layer 28. Note that the thickness and carrier concentration of contact layer 514 are merely examples, and can be appropriately changed.

Contact layer 514 is formed by epitaxial growth after second opening 30 is formed. Bottom surface 30a of second opening 30 is subjected to etching damage when the second opening 30 is formed, whereas an upper surface of contact layer 514 is not subjected to etching damage. Therefore, in a case where source electrode 34 is brought into contact with contact layer 514, the contact resistance can be reduced as compared with the case of being brought into contact with block layer 14. In this manner, the potential of block layer 14 can be stabilized by electrically connecting source electrode 34 to block layer 14 via contact layer 514.

Third opening 530 is provided between second opening 30 and first opening 20 in plan view of substrate 10. Third opening 530 is an opening provided to reduce the contact resistance between source electrode 34 and 2DEG 23, and may be referred to as source opening. Third opening 530 penetrates electron supply layer 24 and reaches electron transport layer 22. For example, bottom surface 530a of third opening 530 is located lower than an interface between electron transport layer 22 and electron supply layer 24 and lower than a region where 2DEG 23 is generated. Therefore, 2DEG 23 is exposed on side surface 530b of third opening 530. By providing source electrode 34 so as to cover bottom surface 530a and side surface 530b of third opening 530, source electrode 34 and 2DEG 23 can be brought into contact with each other. This can reduce the contact resistance between source electrode 34 and 2DEG 23.

Note that, although FIG. 6 illustrates an example in which side surface 530b of third opening 530 is perpendicular to bottom surface 530a, side surface 530b may be inclined with respect to bottom surface 530a. Furthermore, third opening 530 does not necessarily penetrate electron supply layer 24. By thinning electron supply layer 24 located between source electrode 34 and 2DEG 23, the contact resistance can be reduced.

Note that, in nitride semiconductor device 501 according to the present exemplary embodiment, third opening 530 may not be provided. For example, contact layer 514 may not cover a portion in the vicinity of the interface between electron supply layer 24 and electron transport layer 22 in side surface 30b of second opening 30. In this case, source electrode 34 can be brought into contact with 2DEG 23 exposed on side surface 30b of second opening 30. The contact resistance to 2DEG 23 can be reduced without providing third opening 530.

Contact layer 514 and third opening 530 may be provided in nitride semiconductor devices 101, 201, 301, and 401 according to the second exemplary embodiment to the fifth exemplary embodiment. Furthermore, similarly to intermediate layer 326 according to the fourth exemplary embodiment, intermediate layer 26 of nitride semiconductor device 501 may have a stacked structure of a GaN layer and an AlGaN layer.

### Other exemplary embodiments

The nitride semiconductor device according to one or more aspects has been described above on the basis of the exemplary embodiments, but the present disclosure is not limited to these exemplary embodiments. Configurations in which various modifications conceivable by those skilled in the art are applied to the present exemplary embodiments and configurations constructed by combining constituent elements in different exemplary embodiments are also included in the scope of the present disclosure without departing from the gist of the present disclosure.

For example, intermediate layer 26 or 226 may include, as a main component, a material other than the nitride semiconductor. For example, intermediate layer 26 or 226 may include, as a main component, a metal oxide such as gallium oxide or nickel oxide. Alternatively, intermediate layer 26 or 226 may include, as a main component, an insulating material such as silicon oxide or silicon nitride.

Furthermore, for example, second opening 30 may not be provided. In this case, source electrode 34 is provided on upper surface 24a of electron supply layer 24, and is electrically connected to 2DEG 23 via electron supply layer 24.

Furthermore, for example, in nitride semiconductor devices 1, 101, 201, 301, 401, and 501 according to the respective exemplary embodiments, a high-resistance layer having a resistance higher than that of block layer 14 may be provided between drift layer 12 and block layer 14. The high-resistance layer is, for example, a nitride semiconductor layer including carbon-doped GaN (C-GaN) as a main component. The carbon concentration of the high-resistance layer is, for example, more than or equal to 3 × 10¹⁷ cm⁻³, but may be more than or equal to 1 × 10¹⁸ cm⁻³. The high-resistance layer is provided in contact with each of drift layer 12 and block layer 14. The high-resistance layer may include n-type impurities such as Si. The concentration of the n-type impurities included in the high-resistance layer is lower than the carbon concentration and the oxygen concentration of the high-resistance layer, and may be, for example, less than or equal to 5 × 10¹⁶ cm⁻³, or less than or equal to 2 × 10¹⁶ cm⁻³. By providing the high-resistance layer, punch-through can be suppressed, and the withstand voltage can be increased. Note that, in a case where the high-resistance layer is formed, first opening 20 penetrates the high-resistance layer. As a result, since the high-resistance layer is not located on a path of the drain current when the FET is on, an increase in the on-resistance can be suppressed.

Furthermore, for example, drift layer 12 may have a graded structure in which the impurity concentration (donor concentration) gradually decreases from a substrate 10 side toward a block layer 14 side. Note that the donor concentration may be controlled by Si as a donor, or may be controlled by carbon as an acceptor that compensates for Si. Alternatively, drift layer 12 may have a stacked structure of a plurality of nitride semiconductor layers having different impurity concentrations. Specifically, the drift layer is formed into two layers, a layer having a low donor concentration is disposed below the block layer, and a layer having a high donor concentration is disposed further below the layer having the low donor concentration (that is, on the substrate side). Then, by providing first opening 20 so as to penetrate the layer having a low donor concentration, a current flows through the layer having a high donor concentration through first opening 20 when the transistor is on, so that on-resistance can be reduced. On the other hand, when the transistor is off, a high electric field is held by the layer having a low donor concentration, so that both low on-resistance and high withstand voltage can be achieved.

Furthermore, the conductivity type of intermediate layer 26, 226, or 326 may be i-type. The conductivity types of GaN layer 326A and AlGaN layer 326B may be i-type. This makes it possible to suppress diffusion of p-type impurities from p-type shielding layer 27 or 127. That is, intermediate layer 26, 226, or 326 may include p-type impurities. Since the expansion of the depletion layer to the channel portion can be suppressed, a decrease in the concentration of 2DEG 23 can be suppressed, and the on-resistance can be reduced.

Furthermore, intermediate layer 26, 226, or 326 may be provided only in a portion along inclined side surface 20b of first opening 20. Specifically, a portion of intermediate layer 26, 226, or 326 parallel to the principal surface of substrate 10 may not be provided. For example, in a case where the cross-sectional shape of intermediate layer 26, 226, or 326 is compared to a V shape, a bottom portion of the V shape and a portion extending outward from two upper ends of the V shape may not be provided.

For example, threshold value adjustment layer 28 may contact and cover only a part of the bottom surface of recess 25. That is, the bottom surface of recess 25 may be provided with a portion covered with insulating film 40 without being covered with threshold value adjustment layer 28. For example, an end portion of threshold value adjustment layer 28 on the source electrode 34 side may be located on the bottom surface of recess 25. In this case, 2DEG 23 is not generated when off in a direction immediately below the bottom surface of recess 25 located closer to the source electrode 34 side than threshold value adjustment layer 28. Therefore, since an area in which threshold value adjustment layer 28 electrically connected to gate electrode 32 and 2DEG 23 face each other is reduced, gate-source capacitance Cgs can be reduced.

Note that not only the end portion of threshold value adjustment layer 28 on the source electrode 34 side but also the opposite end portion may be located on the bottom surface of recess 25. That is, threshold value adjustment layer 28 may be provided so as not to contact the side surface of recess 25. Also in this case, since an area where threshold value adjustment layer 28 and 2DEG 23 face each other is reduced, gate-source capacitance Cgs can be reduced.

Furthermore, a side surface of recess 25 on the source electrode 34 side may not be provided, and a bottom surface of recess 25 may extend to immediately below source electrode 34. That is, a part of source electrode 34 may contact and cover a part of the bottom surface of recess 25.

Furthermore, for each of the exemplary embodiments described above, various changes, replacements, additions, omissions, and the like can be made within the scope of claims or equivalents thereof.

According to the present disclosure, on-resistance can be reduced.

The nitride semiconductor device according to the present disclosure is useful as, for example, a power device used in a power supply circuit, an inverter circuit, or the like of electric equipment.

What is claimed is:

1. A nitride semiconductor device comprising:
a substrate;
a first nitride semiconductor layer of n-type disposed above the substrate;
a second nitride semiconductor layer of p-type disposed above the first nitride semiconductor layer;
an electron transport layer and an electron supply layer each disposed in order from the substrate side, the electron transport layer and the electron supply layer covering an inner surface of a first opening that penetrates the second nitride semiconductor layer and reaches the first nitride semiconductor layer, and covering above the second nitride semiconductor layer;
a third nitride semiconductor layer of p-type disposed above the electron supply layer;
an intermediate layer disposed between the electron supply layer and the third nitride semiconductor layer at a position overlapping the first opening in plan view of the substrate;
a gate electrode disposed above the electron supply layer at a position overlapping the second nitride semiconductor layer without overlapping the first opening in plan view of the substrate;
a source electrode disposed above the second nitride semiconductor layer and apart from the gate electrode;
a shielding electrode disposed above the third nitride semiconductor layer at a position overlapping the first opening in plan view of the substrate, and electrically connected to the source electrode; and
a drain electrode disposed below the substrate,
wherein the intermediate layer includes a side surface covered with the third nitride semiconductor layer.

2. The nitride semiconductor device according to claim 1, wherein
the third nitride semiconductor layer includes:
a shielding portion that overlaps the first opening in plan view of the substrate and is electrically connected to the shielding electrode, and
a gate portion that overlaps an upper surface of the second nitride semiconductor layer in plan view of the substrate and is electrically connected to the gate electrode.

3. The nitride semiconductor device according to claim 2, wherein
the side surface of the intermediate layer is covered with the shielding portion.

4. The nitride semiconductor device according to claim 3, wherein
an end of the shielding portion on the source electrode side overlaps an upper surface of the second nitride semiconductor layer in plan view of the substrate.

5. The nitride semiconductor device according to claim 3, wherein
an end of the shielding portion on the source electrode side overlaps an inclined surface of the first opening in plan view of the substrate.

6. The nitride semiconductor device according to claim 2, wherein
the side surface of the intermediate layer is covered with the gate portion.

7. The nitride semiconductor device according to claim 6, wherein
the intermediate layer includes a GaN layer including GaN as a main component, and an AlGaN layer disposed above the GaN layer and including AlGaN as a main component.

8. The nitride semiconductor device according to claim 7, wherein
the AlGaN layer has an Al composition ratio of more than or equal to 10%.

9. The nitride semiconductor device according to claim 1, wherein
the electron supply layer includes Al, and
the electron supply layer has an Al composition ratio of more than or equal to 10%.

10. The nitride semiconductor device according to claim 2, wherein
the electron supply layer includes a recess at a position overlapping the upper surface of the second nitride semiconductor layer in plan view of the substrate, and
the gate portion is disposed in contact with at least a part of a bottom surface of the recess.

11. The nitride semiconductor device according to claim 2, wherein
the electron supply layer includes an upper surface that is a flat surface between the source electrode and the shielding portion and within a range overlapping the upper surface of the second nitride semiconductor layer in plan view of the substrate.

12. The nitride semiconductor device according to claim 1, wherein
the source electrode is electrically connected to the second nitride semiconductor layer via a second opening that penetrates the electron supply layer and the electron transport layer and reaches the second nitride semiconductor layer.

13. The nitride semiconductor device according to claim 12, further comprising a fourth nitride semiconductor layer of p-type disposed in contact with the second nitride semiconductor layer in the second opening,
wherein the source electrode is in contact with the fourth nitride semiconductor layer.

14. The nitride semiconductor device according to claim 1, wherein
the intermediate layer includes a nitride semiconductor as a main component.

15. The nitride semiconductor device according to claim 1, wherein
the intermediate layer has an n-type conductivity.

16. The nitride semiconductor device according to claim 15, wherein
the intermediate layer has a carrier concentration of more than or equal to 2 × 10¹⁷ cm⁻³.

17. The nitride semiconductor device according to claim 1, wherein
the intermediate layer has an i-type conductivity.

18. The nitride semiconductor device according to claim 17, wherein
the intermediate layer includes p-type impurities.

19. The nitride semiconductor device according to claim 1, wherein
the intermediate layer has a film thickness of from 20 nm to 500 nm inclusive.
